(19) United States
(12) Patent Application Publication
(10) Pub. No.: US 2025/0344518 A1
(43) Pub. Date: Nov. 6, 2025

(54) METHOD FOR MANUFACTURING A SOLAR PANEL HAVING A SOLAR CELL AND INTEGRATED CIRCUITS ON THE SAME SILICON WAFER

(71) Applicant: JBB Advanced Technologies, LLC, Carrollton, TX (US)

(72) Inventors: John Taylor Billingsley, JR., Dallas, TX (US); Ronald Lyle Chichester, Waller, TX (US)

(73) Assignee: JBB Advanced Technologies, LLC, Dallas, TX (US)

(21) Appl. No.: 18/653,812

(22) Filed: May 2, 2024

(51) Int. Cl. H01L 27/142

(52) U.S. Cl. CPC H10F 19/50

(57) ABSTRACT

A method for manufacturing a solar panel having a solar cell and integrated circuits on the same silicon wafer is disclosed. The solar panel include two groups of semiconductor wafers. Each of the first group of semiconductor wafers includes a solar cell for generating direct current via the photovoltaic effect. Each of the second group of semiconductor wafers includes a solar cell for generating direct current via the photovoltaic effect, and some integrated circuits arranged to perform computations. The integrated circuits are solely powered by the solar cell from the second group and other solar cells from the group of semiconductor wafers.

### TECHNICAL FIELD

The present invention relates to solar panels in general, and in particular to a method for manufacturing a solar panel having a solar cell and integrated circuits on the same silicon wafer.

### BACKGROUND

In the modern world, the need for electrical power is ubiquitous. However, many electrical power generators, such as coal or fossil fuel power plants, generate not only electrical power but also pollutants that are environmentally harmful while exhausting earth resources. In an effort to avoid these drawbacks, electrical energy obtained from renewable energy sources is increasingly popular in a global scale. For example, electrical power can be generated by using photovoltaic solar panels to harvest energy of the sun. Moreover, solar panels are particularly well-suited to stand-alone applications in isolated areas. The tremendous growth in the solar industry is helping to achieve a cleaner and more sustainable energy future. At the same time, cryptocurrencies, exemplified by Bitcoin, has also become quite popular. Consensus algorithms are required by cryptocurrencies, and computers and/or special computational hardware typically are utilized to perform such consensus algorithms. However, consensus algorithm computations are very power intensive and thus places a strain on local power grids.

### SUMMARY

Instead of drawing power from a local power grid, solar panels can be utilized to generate electrical power to support consensus algorithm computations. Solar panels are typically designed to provide power to devices external to the solar panels, much like a power generator. The present invention provides a solar panel having integrated circuits (ICs) embedded within the solar panel. These ICs can be logic gates, processors, network interface devices, application specific integrated circuits (ASICs), field programmable gate arrays (FPGAs), or other types of circuits that are capable of performing complex computations, such as consensus algorithms. The power to operate these ICs comes directly from the integrated solar panels.

In accordance with one embodiment of the present invention, a solar panel include two groups of semiconductor wafers. Each of the first group of semiconductor wafers includes a solar cell for generating direct current via the photovoltaic effect. Each of the second group of semiconductor wafers includes a solar cell for generating direct current via the photovoltaic effect, and some ICs arranged to perform computations. The ICs are solely powered by the solar cell from the second group and other solar cells from the group of semiconductor wafers.

All features and advantages of the present invention will become apparent in the following detailed written description.

### BRIEF DESCRIPTION OF THE DRAWINGS

The invention itself, as well as a preferred mode of use, further objects, and advantages thereof, will best be understood by reference to the following detailed description of an illustrative embodiment when read in conjunction with the accompanying drawings, wherein:

FIG. 1 is a flow diagram of a method for manufacturing a solar panel having a solar cell and integrated circuits on the same wafer, according to one embodiment; and

FIG. 2 is a block diagram of a solar panel manufactured by using the method from FIG. 1, according to one embodiment.

### DETAILED DESCRIPTION OF A PREFERRED EMBODIMENT

A series of processing steps is required to manufacture a photovoltaic (PV) solar panel. The main raw materials include glass, polymers for encapsulation, aluminum for frame, silicon for solar cells, and silver and copper for conductors. In accordance with one embodiment of the present invention, a series of integrated circuit (IC) fabrication steps is incorporated within the solar panel manufacturing steps. As a result, solar cells and ICs can be manufactured at the time by sharing some processing steps. In addition, the ICs will be embedded within the solar cells, and the ICs will be solely powered by the solar cells within a solar panel.

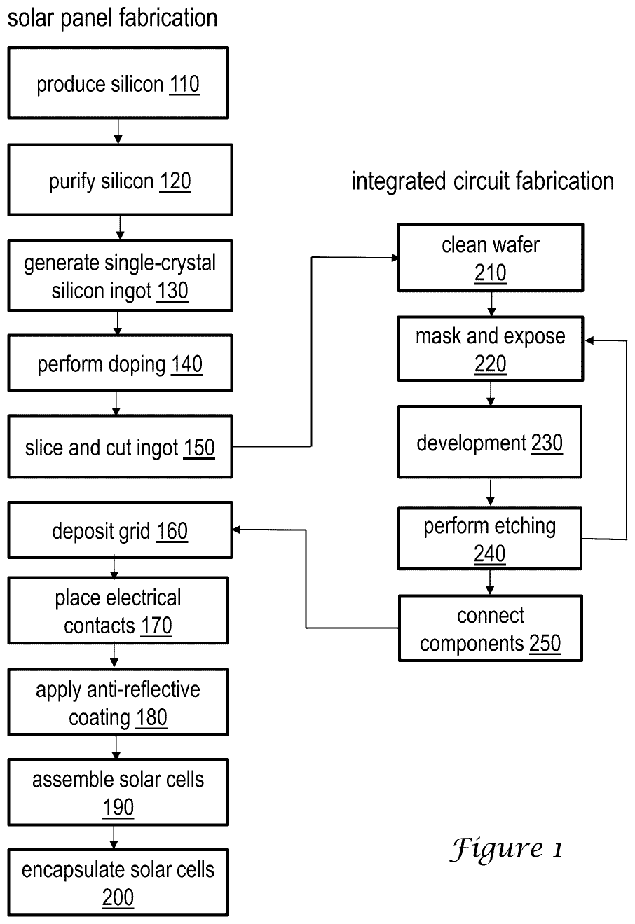

Referring now to the drawings and in particular to FIG. 1, there is illustrated a flow diagram of a method for manufacturing a solar panel having a solar cell and integrated circuits on the same silicon wafer, according to one embodiment. The manufacturing of solar cells and the manufacturing of ICs both start with silicon production and both use the same silicon wafer.

Silicon Production: Starting at block 100, high-purity silicon is produced, as shown in block 110. This can be accomplished by placing silicon dioxide into an electric arc furnace and by applying a carbon arc to remove any oxygen from the molten silicon. Although the carbon dioxide and molten silicon that result from this process yield silicon with only 1% impurity, it is not pure enough for solar cell production.

Silicon Purification: Thus, the silicon needs to be purified, as depicted in block 120, by using a float zone technique that allows a rod of impure silicon to pass through a heated zone a couple of times in the same direction. With each pass, the impurities are dragged towards one end until the silicon is completely purified. At this point, the silicon is polycrystalline.

Single-crystal Silicon Ingot Generation: A single-crystal silicon ingot (or boule) is generated, as shown in block 130, by using the Czochralski method, which involves dipping the silicon seed crystal into the melted polycrystalline silicon. The seed crystal is withdrawn and rotated during the process to eliminate all impurities and form a cylindrical ingot of pure single-crystal silicon.

Doping: A small amount of impurities are intentionally introduced into the intrinsic semiconductor to modulate its optical, electrical, and structural properties, as depicted in block 140. One way of doping is to introduce a small amount of boron during the Czochralski process (in block 130 above), and the silicon is then sealed back-to-back and placed in a furnace to be heated to slightly below the melting point of silicon (i.e., 1,410° C.) in the presence of phosphorous gas. The phosphorous atoms “burrow” into the silicon, which is more porous because it is close to becoming a liquid. The temperature and time are carefully controlled to ensure a uniform junction of proper depth. Alternatively, silicon can be doped with phosphorous by using a small particle accelerator to shoot phosphorous ions into the ingot. By controlling the speed of the phosphorous ions, it is possible to control their penetrating depth. Doping helps to create regions (within a silicon wafer) where electrons can move freely, allowing for efficient conversion of sunlight into electricity.

Ingot Slicing and Cutting: A diamond-edged saw is used to slice the ingot into round silicon wafers, as shown in block 150. These round wafers are further cut into rectangular or hexagonal shapes. Rectangular or hexagonal wafers are used in solar cells because they can be fitted together perfectly, thereby utilizing all available space on the front surface of a solar panel.

### Fabrication of Integrated Circuits

The fabrication of ICs involves a series of steps. Lithography is a critical step in the IC fabrication process, as it allows for the precise creation of tiny features on a silicon wafer. The process involves exposing the silicon wafer to light through a mask, which contains the desired pattern. The exposed areas of the silicon wafer then undergo chemical changes that etch away the unwanted material, resulting in the desired pattern.

The lithography process can be broken down into several stages:

Wafer preparation: This involves cleaning the silicon wafer and applying a layer of photoresist material to its surface, as shown in block 210.

Exposure: A mask is then placed in contact with the silicon wafer, and light is passed through the mask to expose the silicon wafer, as depicted in block 220. This mask is typically made of a light-sensitive material, such as photoresist, and is designed to transfer a desired pattern onto the silicon wafer. The exposed areas of the wafer will undergo chemical changes that etch away the unwanted material.

Development: After exposure, the silicon wafer is treated with a developer solution that selectively removes the unexposed photoresist material, as shown in block 230. This leaves behind the patterned photoresist layers, which can then be used as a template for etching the silicon wafer.

Etching: Next, an etchant gas is utilized to remove the unwanted material from the silicon wafer, as depicted in block 240. The etchant gas selectively removes the material based on its chemical properties, leaving behind the desired pattern on the silicon wafer.

Remasking: After the etching process has been completed, the process can return to block 220 so that the silicon wafer can be coated with a new layer of photoresist material. This is done by applying a new mask that contains a desired pattern, and repeating the exposure, development, and etching steps.

Connecting components: After multiple rounds of lithography, the silicon wafer will contain the desired pattern of transistors, capacitors, and other components. The final step is to connect these components, as shown in block 250.

At this point, the IC fabrication is completed and the process returns back to the solar cells/panels fabrication steps. The ICs can be application specific integrated circuits (ASICs), field programmable gate arrays (FPGAs), or other types of circuits that are capable of performing complex computations, such as consensus algorithms.

Grid Deposition: A thin layer of metal grids is then deposited onto the silicon wafers using a technique called sputtering, as depicted in block 160. These grids help to guide the electrons produced by the sunlight and improve the overall efficiency of the solar panel.

Electrical Contacts Placement: Solar cells are connected to the receiver of the produced current with the use of extremely thin electrical contacts, as shown in block 170. Once these extremely thin electrical contacts are placed on the solar cells' exposed areas, thin strips of tin-coated copper are placed between solar cells.

Anti-Reflective Coating Application: A titanium dioxide or silicon oxide anti-reflective coating is deposited on the silicon wafer using techniques such as chemical vapor deposition (CVD) or physical vapor deposition (PVD), as depicted in block 180, in order to minimize the amount of sunlight lost due to reflection.

Assembly: Individual wafers (solar cells) are then assembled onto a supporting frame using a vacuum-based robotic system, as shown in block 190. This assembly process is critical for ensuring that the solar panel is free from defects and can operate efficiently.

Solar Cell Encapsulation: The finished solar cells are sealed into ethylene vinyl acetate or silicon rubber, as depicted in block 200, before they are placed into an aluminum frame with a Tedlar or Mylar back-sheet and a plastic or glass cover to protect them from environmental factors such as heat and moisture.

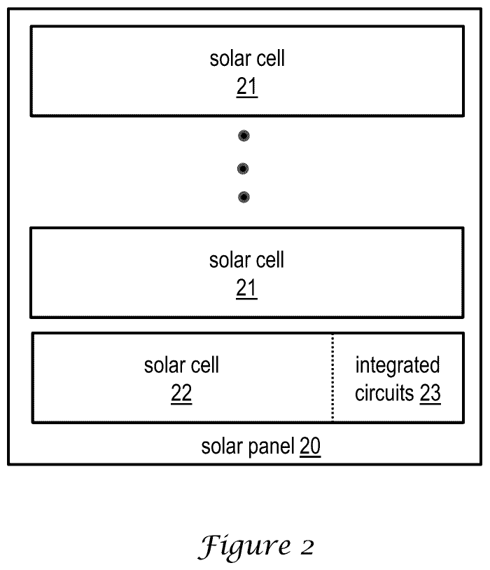

With reference now to FIG. 2, there is illustrated a block diagram of a solar panel manufactured by using the method from FIG. 1, according to one embodiment. As shown, multiple solar cells 21 and computational ICs 22 are installed on one side of a solar panel 20. Solar panels can come in a wide variety of sizes. For the present embodiment, solar panel 20 is approximately 5 feet long and 3 feet wide such that the resulting weigh would be just over 40 pounds and can be handled by a single individual, which makes it easier to install an array of panels with a small crew. Since a 40-pound solar panel roughly translate to approximately 60 wafers, solar panel 20 contains 60 to 72 wafers, and each wafer may contain one solar cell or a combination of solar cell and computational ICs. Assuming the surface area of each wafer is 23,900 mm², then (theoretically) each wafer can hold approximately 5 million ICs. The IC area required for implementing SHA-256 algorithm is approximately 4,916.7 μm² (or 0.0049167 mm²) and consumes approximately 4 mW of electrical power.

Computational ICs 22 are solely powered by solar cells 21. The current (and power) output of a solar cell depends on its efficiency and size (surface area) of the solar cell, and it is also proportional to the intensity of sunlight striking the surface of the solar cell. For example, under peak sunlight conditions, a solar cell having a surface area of 160 cm² (˜25 in²) can produce about 2 W peak power. If the sunlight intensity were 40% of peak power, this solar cell would produce about 0.8 W. Utility-scale solar panel solar cells should be able to produce about 5.27 W at peak conditions, and 5.27 W is sufficient to power 1,559 ICs. 1,559 ICs take up (at minimum) 7.76 mm², which is 0.0325% of the total surface area of the solar cell. Thus, the outputs from all the solar cells within solar panel 20 would be needed to power roughly 1,500 ICs that take up less than 1% of the surface area on solar panel 20. Some extra space on solar panel 20 and solar cells are required to be devoted to input/output data bus, or pins, or wiring that enables processing unit to send inputs to the ICs, as well as retrieve corresponding outputs from the ICs.

As an alternative embodiment, solar cells 21 and computational ICs 22 can be formed on opposite sides of solar panel 20, but computational ICs 22 are still solely powered by solar cells 21.

Although some wafers include both solar cells and computational ICs, ideally, the entire output of a solar cell would be consumed by the ICs that take up a minuscule amount of surface area of the solar cell. However, a wafer can be devoted only to computational ICs, and have it powered by solar cells on the same solar panel. But the preferred embodiment is to have all the computational ICs located on the same wafer as the solar cell.

As the computational ICs will only be able to perform a single algorithm (such as SHA-256), some other device will need to be able to funnel jobs to the computational ICs, as well as obtain the results from the computational ICs. That device (such as a central processing unit, memories, network interface, etc.) could be embedded on solar panel 20, or it could be in a separate unit that is attached to solar panel 20, or it could be a remote server.

Most solar cells output 0.5 to 0.6 V DC under an open load. This level of potential is likely insufficient for powering the computational ICs, which operate at 1.5 V. Furthermore CPUs, network interface cards, and RAM typically operate within a voltage range of 1.5 to 12 V. Thus, the design of the PV effect portion of the solar cell may need to be modified in order to increase the voltage (with a corresponding loss of current). The key is voltage control. A threshold diode is probably needed so that the computational ICs does not turn on if there is insufficient voltage from the solar cells (or turn off if and when a cloud or darkness overtake solar panel 50).

Voltage outputs of solar cells can be connected to voltage inputs of computational ICs by using aluminum and/or copper interconnects.

As has been described, the present invention provides a solar panel having computational ICs embedded within the solar panel. These computational ICs are capable of performing complex computations. The portion of the solar panel that is devoted to computation IC is adjustable. In other words, based on what computation is needed, the proportion of the solar panel that is devoted to the computational ICs depends on needs, and the remaining portion of the solar panel is reserved for the production of electricity.

While the invention has been particularly shown and described with reference to a preferred embodiment, it will be understood by those skilled in the art that various changes in form and detail may be made therein without departing from the spirit and scope of the invention.

What is claimed is:

1. A solar panel comprising:
a first group of semiconductor wafers, wherein each of said first group of semiconductor wafers includes a solar cell for generating direct current (DC) from the photovoltaic effect; and
a second group of semiconductor wafers, wherein each of said second group of semiconductor wafers includes:
a solar cell for generating DC from the photovoltaic effect; and
a plurality of integrated circuits (ICs) constructed on the same semiconductor wafer as said solar cell, wherein said ICs are arranged to perform computations, wherein said ICs are solely powered by said solar cell from said second group and other solar cells from said first group of semiconductor wafers.

2. The solar panel of claim 1, wherein said plurality of ICs includes logic gates.

3. The solar panel of claim 1, wherein said plurality of ICs includes a central processing unit.

4. The solar panel of claim 1, wherein said plurality of ICs includes memory devices.

5. The solar panel of claim 1, wherein said plurality of ICs includes a network interface card.

6. The solar panel of claim 1, wherein said plurality of ICs includes circuits for performing consensus algorithms.

7. The solar panel of claim 1, wherein said semiconductor wafer is made of silicon.

8. A method for manufacturing solar panels, said method comprising:
producing a single-crystal silicon ingot;
doping said silicon ingot;
slicing and cutting said silicon ingot into silicon wafers;
performing lithography on areas of said silicon wafers intended to be computational integrated circuit (IC) components;
connecting said computational IC components within said silicon wafers;
depositing grids on areas of said silicon wafers intended to be solar cells;
placing electrical contacts on said solar cells within said silicon wafers; and
encapsulating said solar cells and said computational IC components to form a solar panel.

9. The method of claim 8, wherein said performing lithography further includes masking, developing and etching.

10. The method of claim 8, wherein said method further includes apply anti-reflective coating on said silicon wafer.
